(19) United States
(12) Patent Application Publication
(10) Pub. No.: US 2025/0380517 A1
(43) Pub. Date: Dec. 11, 2025

(54) X-RAY DETECTION DEVICE AND MANUFACTURING METHOD THEREOF

(71) Applicant: KETEK GmbH Halbleiter- und Reinraumtechnik, Muenchen (DE)

(72) Inventors: Michael Darius Fraczek, Pliening (DE); Oliver Scheid, Muenchen (DE); Jörg Rumpff, Egling (DE); Andreas Pahlke, Brunnthal (DE)

(21) Appl. No.: 18/736,295

(22) Filed: Jun. 6, 2024

(51) Int. Cl. H01L 31/08; H01L 31/02; H01L 31/0264; H01L 31/18

(52) U.S. Cl. CPC H10F 30/301; H10F 71/00; H10F 77/12; H10F 77/93

(57) ABSTRACT

In an embodiment an X-ray detection device includes a circuit board supporting conductor tracks on a base body and an X-ray detector mounted on the based body and configured to detect X-rays within a relevant energy detection range of the X-ray detection device, wherein a sensitive section of the circuit board is free of contamination materials prone to emit contaminating X-ray emission within the relevant energy detection range upon being excited with X-rays, and wherein in the sensitive section the base body and the conductor tracks consist essentially of circuit board materials having an atomic number of at most 14.

### TECHNICAL FIELD

An X-ray detection device is provided. A method for manufacturing such an X-ray detection device is also provided.

### BACKGROUND

Documents US 2020/0105948 A1, US 2022/0320353 A1 and US 2013/0037717 A1 refer to X-ray detectors.

Documents U.S. Pat. No. 8,494,119B2 and U.S. Pat. No. 7,618,906B2 refer to windows for X-rays.

### SUMMARY

Embodiments provide an X-ray detection device with improved limits of detection.

According to at least one embodiment, the X-ray detection device comprises a circuit board. The circuit board carries one or a plurality of conductor tracks. The conductor tracks may also be referred to as electric wiring on the board. There can be one or a plurality of layers of electric wiring on the circuit board, either on one or on two main sides of the circuit board.

According to at least one embodiment, the X-ray detection device comprises one or a plurality of X-ray detectors. The at least one X-ray detector is located on the circuit board. For example, the at least one X-ray detector is configured to detect X-rays. The X-rays to be detected may have a photon energy within a relevant energy detection range of the X-ray detector. In other words, the at least one X-ray detector is configured to detect photons having energies within the detection range, hence, the detection range can be an energy range of interest, for example, suitable for material investigation. For example, the energy detection range starts below 2 keV or 1 keV or below 0.1 keV; alternatively or additionally, the energy detection range ends above 25 keV or above 50 keV or above 100 keV or above 0.2 MeV. It is possible that different kinds of X-ray detectors are combined with each other in the X-ray detection device.

The X-ray detector may comprise an active volume. The active volume is the region within the X-ray detector within which incident radiation is converted into electrons and then read out, for example. The X-ray detector can be a detector chip comprising at least one semiconductor material. For example, the X-ray detector is a PIN photodiode or a silicon drift detector, SDD for short.

According to at least one embodiment, a sensitive section of the circuit board is free of contamination materials prone to emit contaminating X-ray emission within the relevant energy detection range upon being excited with X-rays, like stray X-rays. For example, the sensitive section includes all regions of the circuit board from which X-rays of a specific photon energy are able to directly reach the active volume of the X-ray detector.

For example, a section is a three-dimensional volume. A section may include at least part of the conductor tracks and at least part of the base body.

There is just one sensitive section or there is a plurality of sensitive sections. For example, the sensitive section is an upper half of the circuit board next to the X-ray detector or is an area of the circuit board below and next to the X-ray detector when seen in top view of the X-ray detector.

Stray X-rays are, for example, fluorescence or scattered X-rays coming from another component of the X-ray detection device upon being hit by X-rays coming from a sample or an X-ray source, or X-rays directly coming from the X-ray source. The stray X-rays have an energy of, for example, at least 1.5 kV, corresponding to characteristic aluminum K_{α1} radiation so that in principle the stray X-rays can trigger X-ray fluorescence in various materials. Thus, the sensitive section of the circuit board is made of materials that cannot be excited by X-rays, like the stray X-rays, and fluorescing in the relevant energy detection range. For example, the materials of the sensitive section fluoresce only in a low-energy range below the relevant energy detection range so that possible X-ray fluorescence from the sensitive section does not influence a measurement with the X-ray detector, for example, in course of material composition analysis.

According to at least one embodiment, in the sensitive section the base body and the conductor tracks are made of circuit board materials having an atomic number of at most 14, that is, having an atomic number of silicon, Si, or having a lower atomic number. Thus, possible elements are, for example, nitrogen, N, oxygen, O, aluminum, Al, and/or boron, B.

By using such materials for the sensitive section it can be assured that possible X-ray fluorescence from the sensitive section is at comparable low energies not disturbing material composition analysis of, for example, in a sorting process of metals to be recycled.

That the sensitive section is made of circuit board materials having an atomic number of at most 14 means, for example, that the sensitive section consists only of materials having an atomic number of at most 14 by at least 95% by mass or by at least 98% by mass or by at least 99% by mass or by at least 99.5% by mass or by at least 99.9% by mass or by at least 99.98% by mass. Hence, there can be very small amount of contaminating materials having an atomic number larger than 14 but such materials do not lead to a strong X-ray signal in the X-ray detector due to their small amount and/or because their X-ray fluorescence is absorbed by components of the circuit board or the X-ray detector itself so that said X-ray fluorescence cannot reach the active volume of the X-ray detector.

In at least one embodiment, an X-ray detection device comprises a circuit board carrying conductor tracks on a base body, and an X-ray detector mounted on the base body and configured to detect X-rays within a relevant energy detection range of the X-ray detection device. A sensitive section of the circuit board is free of contamination materials prone to emit contaminating X-ray emission within the relevant energy detection range upon being excited with X-rays, like stray X-rays. In the sensitive section the base body and the conductor tracks are made of circuit board materials having an atomic number of at most 14.

According to at least one embodiment, in the sensitive section or the overall base body is made of at least one of a plastic material, an aluminum oxide, a silicon oxide, a boron nitride, a silicon nitride, an aluminum nitride, a silicon carbide or a boron carbide, or their modifications. This applies, for example, with a purity of at least 95 by mass or of at least 98% by mass or of at least 99% by mass or of at least 99.5% by mass or of at least 99.9% by mass or of at least 99.98% by mass. Modifications of the afore-mentioned materials include, for example, aluminum oxide ceramics, sapphire, quartz, glass, and mixtures thereof.

According to at least one embodiment, in the sensitive section or on the whole base body the conductor tracks are made of aluminum. This applies, for example, with a purity of at least 95 by mass or of at least 98% by mass or of at least 99% by mass or of at least 99.5% by mass or of at least 99.9% by mass or of at least 99.98% by mass.

For example, the circuit board is a high-temperature co-fired ceramics based, for example, on aluminum oxide or a high-purity aluminum oxide ceramics made by another technology. For example, plastic materials include polyimides, PI, or polyether ether ketones, PEEK. Concerning the purity, the same as above may apply.

According to at least one embodiment, the circuit board further comprises one or a plurality of electrical through-connections running from a first main side to an opposite, second main side of the circuit board. By means of the at least one electrical through-connection, an electric contact can be made between the two main sides of the circuit board.

According to at least one embodiment, one, some or all of the electrical through-connections are made of the circuit board materials. That is, the respective at least one electrical through-connection can consist of materials having an atomic number of at most 14 with the above-mentioned purities. For example, the electrical through-connections are made of aluminum.

According to at least one embodiment, the electrical through-connection comprises a hole and an electrically conductive coating covering side faces and optionally a rim of the hole on one or on both main sides of the circuit board. The hole or the side faces of the hole may partially, predominantly or completely be filled with the electrically conductive coating. For example, the electrically conductive coating is of aluminum, for example, with the purities stated above. The rim may completely or partially surround the hole and may be in direct contact with the hole all around. For example, the hole is of cylindric shape or has the shape of a truncated cone. It is possible that different kinds of electrical through-connections are present, for example, having different shapes and/or material compositions.

According to at least one embodiment, the electrically conductive coating and/or the rim of the hole is in direct contact with the conductor tracks. Hence, the at least one electrical through-connection can electrically be contacted by means of at least one of the conductor tracks.

According to at least one embodiment, the circuit board further comprises one or a plurality of insensitive sections. The at least one insensitive section is different from the sensitive section. For example, the at least one insensitive section includes at least one of the contamination materials having an atomic number greater than 14 and possibly prone to emit contaminating X-ray emission within the relevant energy detection range upon being excited with X-rays, like stray X-rays. In other words, the at least one insensitive section may produce X-ray fluorescence within the relevant energy detection range when being hit by X-rays.

According to at least one embodiment, the insensitive section is shielded from the sensitive section and/or from the active volume of the X-ray detector concerning the relevant energy detection range. That is, X-ray fluorescence of the insensitive section does not hit or does not hit in a significant amount the active region. For example, at most 1% or at most 10% of the X-ray fluorescence of the insensitive section can reach the active volume. Hence, an area between the active volume and the respective insensitive section has an optical density, that is, a decadic absorbance

$$A = {log}_{10} \frac{incoming radiant flux}{transmitted radiant flux} ,$$

of at least one or of at least two or of at least three or of at least four concerning the relevant energy detection range. Hence, X-ray fluorescence of the insensitive section does not or does not significantly influence the measurement of X-rays of the X-ray detector.

According to at least one embodiment, the at least one X-ray detector is mounted in the at least one sensitive section. Hence, seen in top view, the first main side can be free of the insensitive section in the region of the X-ray detector. In other words, the location of the X-ray detector may entirely be assigned to the sensitive region.

According to at least one embodiment, the insensitive section is shielded from the X-ray detector. Thus, between the insensitive section and the X-ray detector there can be one or a plurality of shielding elements. The at least one shielding element reduces the amount of X-rays reaching the X-ray detector coming from the insensitive section wherein said X-rays would be within the relevant energy detection range. For example, the X-ray detector is shielded from the insensitive section by a separate shielding element or by a yet present component. For example, the base body itself shields the X-ray detector from the insensitive section.

According to at least one embodiment, the insensitive section of the circuit board comprises one or a plurality of further conductor tracks and/or of further circuit board materials made of or comprising the at least one of the contamination materials. Thus, the insensitive section can comprise materials with an atomic number larger than 14. Thus, upon X-ray excitation due to the stray X-rays the insensitive section may fluoresce in the relevant energy detection range and may thus influence the measurement by the X-ray detector. However, as said X-ray fluorescence is shielded from the X-ray detector, the at least one contamination material can be present in the insensitive section so that, for example, thermal properties of the circuit board or adhesion properties to glue or bond wires can be improved.

In addition, the further conductor tracks and/or the further circuit board materials can be protected from X-rays by means of one or a plurality of shielding elements so that no significant amount of X-rays in the relevant spectral range may reach said further conductor tracks and/or further circuit board materials so that X-ray fluorescence from these further conductor tracks and/or further circuit board materials is inhibited or largely inhibited. However, preferably no such further conductor tracks and/or further circuit board materials are present in close proximity of the X-ray detector.

According to at least one embodiment, the at least one further conductor track is located partially or completely on a side of the base body remote from the X-ray detector. Hence, the base body can serve as the shielding element.

According to at least one embodiment, the circuit board consists of the sensitive section. That is, there is no insensitive section including at least one of the contamination materials having an atomic number greater than 14 and prone to emit contaminating X-ray emission within the relevant energy detection range upon being excited with X-rays, like stray X-rays.

According to at least one embodiment, the X-ray detection device further comprises one or a plurality of distinct shielding elements. Distinct means that said at least one shielding element is different from the circuit board. Thus, said shielding element is no integral part of the circuit board and in particular is not the base body.

According to at least one embodiment, the sensitive section and/or the insensitive section is shielded from the stray X-rays by the shielding element. Hence, for example, the insensitive section is protected from being radiated with X-rays so that X-ray fluorescence of the insensitive section is prevented or reduced. The same may apply for the sensitive section.

According to at least one embodiment, the conductor tracks further comprise one or a plurality of adhesion layers. The at least one adhesion layer may be located directly between the base body and one, some or all of the conductor tracks. Hence, the adhesion layer may touch both the base body and the respective at least one conductor track.

According to at least one embodiment, the adhesion layer comprises at least one of Cr, Ni or Ti, like CrNi. It is possible that the adhesion layer is shielded from the active volume by part of the X-ray detector or by the base body of the circuit board. Further, the adhesion layer may be shielded from the active volume by the conductor tracks made of the at least one material having an atomic number of at most 14.

According to at least one embodiment, a thickness of the adhesion layer amounts to at most 20% or at most 10% or to at most 5% or to at most 3% of a thickness of the at least one respective conductor track. Thus, the adhesion layer is thin, compared with the conductor tracks, and thus do not contribute or do not significantly contribute to disturbing X-rays in the relevant energy detection range.

According to at least one embodiment, the circuit board comprises a plurality of circuit board layers. For example, there are at least two or at least three and/or at most 16 or at most twelve or at most fife of the circuit board layers. The circuit board layers may be sub-boards stacked on top of each other. Thus, all the circuit board layers may be of the same basic design having a base body and conductor tracks at the base body and optionally electric through-connections. However, possibly not all of the circuit board layers need to comprise conductor tracks, that is, one or some of the circuit board layers may consist of the respective base body without having conductor tracks and/or through-connections. The base body of all the circuit board layers may be of the same material, like an aluminum oxide.

According to at least one embodiment, some or all the circuit board layers have different lateral extents, seen in top view onto the X-ray detector. Thus, the respective circuit board layers may not be congruent. For example, the circuit board layers are arranged in a stack having steps so that the overall circuit board may have the shape of a step pyramid or of a step cone. The same may apply for a hole through the circuit board.

According to at least one embodiment, one or some or all of the conductor tracks run along side faces of the circuit board, for example, on side faces of one or some or all of the circuit board layers. That is, the respective conductor track may be applied onto an end face of the respective circuit board or also circuit board layer. Thus, an electrical connection between the main faces of the circuit board may be achieved via the side faces.

According to at least one embodiment, the X-ray detector is electrically connected with a main side of the circuit board facing away from the X-ray detector by means of one or a plurality of bond wires and/or by means of the at least one conductor track running along at least one side face of the circuit board or the circuit board layers. Hence, multiple designs of the electric wiring within the X-ray detection device are enabled. For example, the X-ray detector itself is attached in an electrically insulating manner onto the circuit board, and the electric wiring may thus be independent of attaching the X-ray detector.

According to at least one embodiment, the circuit board further comprises one or a plurality of insulation layers. For example, the at least one insulation layer is of an electrically insulating oxide, like a glass, or carbide or nitride or polymer.

According to at least one embodiment, the base body is of an electrically conductive or semiconductive material. In this case, the insulation layer can be located between the conductor tracks and the base body and may touch the conductor tracks and the base body. The insulation layer may also serve as the adhesion layer or there is additionally the adhesion layer on one or both sides of the insulation layer. The insulation layer may alternatively or additionally be used to electrically separate conductor tracks, applied on the base body, from one another and possibly also from the base body.

Possibly, the at least one insulation layer can be used to electrically insulate stacked and/or crossing conductor tracks from each other. Hence, at least one of the insulation layers or the insulation layer may be used to cover at least one of the conductor tracks. Thus, design options for a layout of the conductor tracks are increased.

In at least one embodiment, the X-ray detection device comprises
a circuit board carrying conductor tracks on a base body;
an X-ray detector mounted on the based body and configured to detect X-rays within a relevant energy detection range of the X-ray detection device; and
a shielding element,
wherein
a sensitive section of the circuit board is free of contamination materials prone to emit contaminating X-ray emission within the relevant energy detection range upon being excited with X-rays, like stray X-rays;
in the sensitive section the base body and the conductor tracks are made of circuit board materials having an atomic number of at most 14;
in the sensitive section the base body is made of an aluminum oxide or a silicon oxide, with a purity of at least 98 mass-%, and the conductor tracks are made of aluminum, with a purity of at least 98 mass-%;
optionally the sensitive section is shielded from the X-rays, like the stray X-rays by the shielding element; and
the sensitive section includes all regions of the circuit board from which X-rays of a specific photon energy are able to directly reach an active volume of the X-ray detector.

A method for manufacturing the X-ray detection device is additionally provided. By means of the method, an X-ray detection device is produced as indicated in connection with at least one of the above-stated embodiments. Features of the X-ray detection device are therefore also disclosed for the method and vice versa.

In at least one embodiment, the manufacturing method is for producing an X-ray detection device, the method comprises
providing the base body of the circuit board,
applying the conductor tracks on the base body,
applying the X-ray detector on the circuit board, and
optionally, encapsulating the X-ray detector by applying a housing cap over the X-ray detector.

### BRIEF DESCRIPTION OF THE DRAWINGS

An X-ray detection device and a manufacturing method described herein are explained in greater detail below by way of exemplary embodiments with reference to the drawings. Elements which are the same in the individual figures are indicated with the same reference numerals. The relationships between the elements are not shown to scale, however, but rather individual elements may be shown exaggeratedly large to assist in understanding.

In FIGS. 1 and 2 are schematic sectional views of exemplary embodiments of X-ray detection devices;

FIGS. 3 and 4 are schematic sectional views of electrical through-connections for exemplary embodiments of X-ray detection devices;

FIGS. 5 and 6 are schematic perspective top views of circuit boards for exemplary embodiments of X-ray detection devices;

FIG. 7 is a schematic representation of an X-ray spectrum;

FIGS. 8 and 9 are schematic sectional views of exemplary embodiments of X-ray detection devices;

FIG. 10 is a schematic top view of the X-ray detection device of FIG. 9;

FIGS. 11 and 12 are schematic sectional views of exemplary embodiments of X-ray detection devices;

FIGS. 13 and 14 are schematic sectional views of circuit boards for exemplary embodiments of X-ray detection devices;

FIG. 15 is a schematic sectional view of an exemplary embodiment of an X-ray detection device; and

FIG. 16 is a schematic block diagram of an exemplary embodiment of a manufacturing method for X-ray detection devices.

### DETAILED DESCRIPTION OF ILLUSTRATIVE EMBODIMENTS

FIG. 1 illustrates an exemplary embodiment of an X-ray detection devices 1. The X-ray detection device 1 comprises a circuit board 3. The circuit board 3 includes first conductor tracks 31 on a first main side 311 of a base body 30. Optionally, there can be second conductor tracks on a second, opposite main side 322, not shown. As in all other embodiments, it is possible that all the conductor tracks are limited to the second main side 322.

On the first main side 311, there is an X-ray detector 2 of the X-ray detection device 1. It is possible that there is no direct electric connection between the X-ray detector 2 and the circuit board 3, that is, the X-ray detector 2 may be attached in an electrically insulating manner onto the circuit board 3 and/or that the respective portions of the circuit board 3 and/or of the X-ray detector 2 being in contact with an adhesive, like a glue or a solder, are electrically insulating.

The X-ray detector 2 is, for example, an SDD. Thus, the X-ray detector 2 can be based on silicon. In the X-ray detector 2, there is an active volume 20, indicated by hatching. For example, the active volume 20 is close to a radiation entrance face 21 of the X-ray detector 2 and may not reach to a bottom side opposite the radiation entrance face 21 and/or to side faces 22 of the X-ray detector 2. Thus, the active volume 20 may only constitute part of the X-ray detector 2 as is possible in all other embodiments. However, for simplicity of the drawings, in the following the active volume 20 may be drawn to completely fill the area assigned to the X-ray detector 2.

In the active volume 20, X-rays are absorbed, and free electrons are generated. These electrons are collected in the X-ray detector 2 and a signal proportional to an energy of the respective X-ray photon is output, for example. The radiation entrance face 21 of the X-ray detector 2 faces away from the circuit board 3. The side faces 22 of the X-ray detector 2 may run oblique, like perpendicular, with the radiation entrance face 20 and the first main side 311.

As shown in FIG. 1, the X-ray detector 2 may be mounted on the conductor tracks 31. A connection between the X-ray detector 2 and the conductor tracks 31 can be a conducting one, for example, via an electrically conductive adhesive or via ball bond connection or soldering, or a non-conducting one, for example, via a non-conductive adhesive, or can partly be electrically conductive and partly be electrically nonconductive. Alternatively, the X-ray detector 2 may be mounted on the base body 30 and electrically connected to the conductor tracks 31 by means of bond wires, not shown. Moreover, the X-ray detector 2 may be mounted on a metallization on the first main side 311 different from the conductor tracks 31 and electrically connected to the conductor tracks 31 by means of bond wires. Such a metallization can also be present in all other embodiments; features for the conductor tracks 31 may apply for such a metallization as well.

The base body 30 is made, for example, of pure aluminum oxide, aluminum nitride or silicon oxide, and the conductor tracks 31 are made, for example, of pure aluminum. Thus, the circuit board 3 can be free or essentially free of materials with an atomic number larger than 14. Hence, if the circuit board 3 is hit by X-rays, no disturbing X-ray fluorescence is generated by the circuit board 3 that may hamper an X-ray spectrum measured with the X-ray detector 2 concerning a relevant energy detection range used, for example, for material analysis of metals to be recycled. Accordingly, in FIG. 1 the whole circuit board 3 corresponds to a sensitive section 35. Sensitive means, for example, that if said section would contain materials having an atomic number larger than 14, then the measurement of an X-ray spectrum could significantly be influenced.

According to FIG. 2, the circuit board 3 further comprises electrical through-connections 33. The through-connections 33 are made of a hole 331. Side faces 333 of the hole 331 are coated with an electrically conductive coating 332. A rim 334 of the through-connections 33 is in direct contact with the conductor tracks 31 on the first main side 311. At the second main side 322, the through-connections 33 can be in direct contact with further conductor tracks 37.

For example, the electrically conductive coating 332 and the first conductor tracks 31 are integrally formed and may thus be of the same material. Contrary to that, the further conductor tracks 37 may be of a different material, like copper, Cu, or gold, Au. Hence, the thermal properties of the circuit board 3 may be improved by the further conductor tracks 37 and/or the electrical properties of the conductor tracks 31 may be improved and/or the manufacturing of the circuit board 3 may be facilitated more efficiently and/or the wire bonding or adhesive bonding onto that further conductor material may be improved, for example. However, the further conductor tracks 37 may be prone to emit X-ray fluorescence upon being hit by X-rays, like stray X-rays. Hence, the further conductor tracks 37 are out of the sensitive section 35 and are located in an insensitive section 36 which can contain materials having an atomic number larger than 14.

The further conductor tracks 37 are relatively remote from the active volume 20. Further, the base body 30 is located between the further conductor tracks 37 and the active volume. Thus, X-ray fluorescence from the further conductor tracks 37 can be shielded from the active volume 20 by means of the base body 30, for example, at least concerning the relevant energy detection range.

A border between the sections 35, 36 is schematically illustrated in FIG. 2 as a dash-dotted line. Other than drawn, this line may also be next to the second main side 322. Said border is drawn as a plane in FIG. 2, but more complex geometries are possible as well.

Otherwise, the same as to FIG. 1 may also apply to FIG. 2, and vice versa.

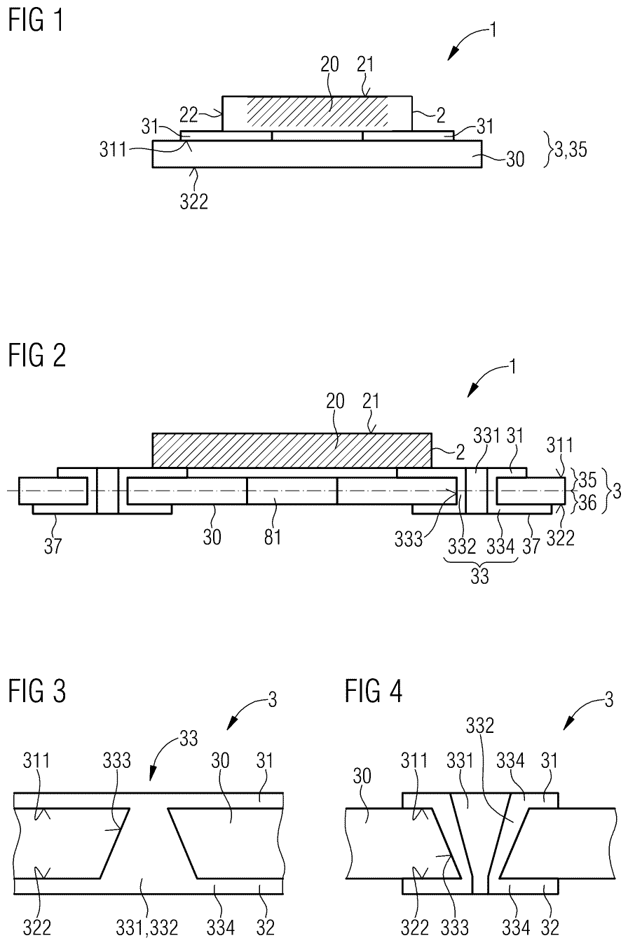

FIGS. 3 and 4 illustrate some possibilities how the electrical trough-connections 33 can be realized. According to FIG. 3, the hole 331 is completely filled with the coating 332. The side faces 333 are inclined with respect to the first main side 311 so that the hole 331 widens towards the second main side 322. Other than conical holes 331, cylindric holes, pyramidal holes or prismatic holes can be used as well. Especially in case if the through-connections are manufactured from both sides, double conical holes or double pyramidal holes are possible as well, that is, holes with a narrower portion in their middle part. According to FIG. 4, the hole 331 is only partially filled with the coating 332, and the hole 331 widens towards the first main side 311.

The direction of widening of the holes 331 can be the opposite of what is actually shown in FIGS. 3 and 4, respectively. Different kinds of electrical trough-connections 33 can be combined with each other in the circuit board 3, for example, having different materials when being located in the sections 35, 36, respectively.

Further, in FIGS. 3 and 4 it is shown that there can be the second conductor tracks 32 at the second main side 322. The second conductor tracks 32 are, for example, of pure aluminum, too, so that the second conductor tracks 32 can be part of the sensitive section 35. Such second conductor tracks 32 can be present in all embodiments of the X-ray detection device 1.

Otherwise, the same as to FIGS. 1 and 2 may also apply to FIGS. 3 and 4, and vice versa.

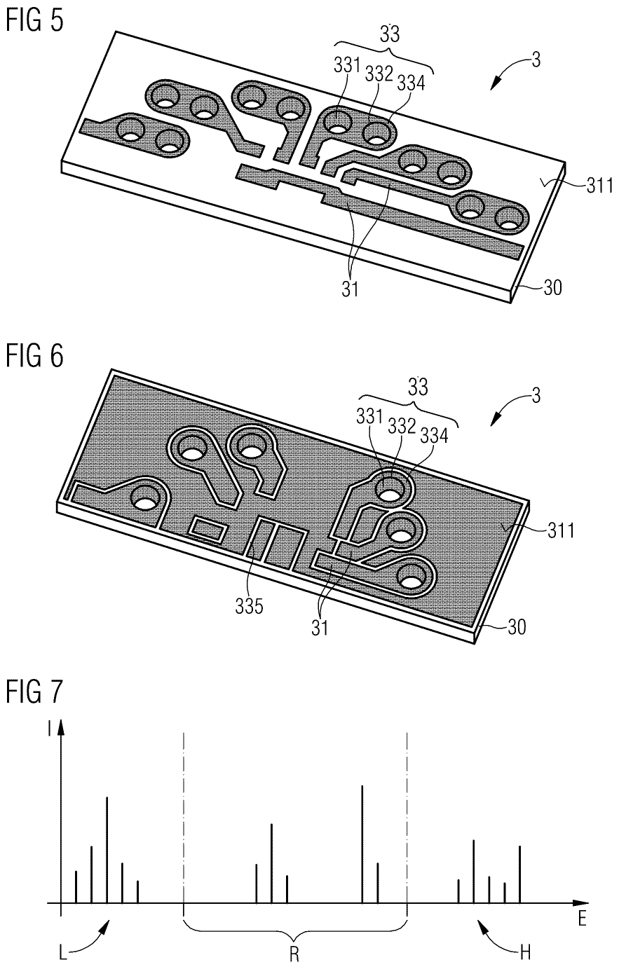

In FIGS. 5 and 6, exemplary embodiments of the circuit board 3 are shown. In FIG. 5 it can be seen that the conductor tracks 31 are applied as strips onto the first main side 311. A width of the strips is, for example, at most 1 mm or at most 0.5 mm or at most 0.2 mm and/or at least 50 μm or at least 10 μm. The conductor tracks 31 can be integrally formed with the coating 332 of the optional through-connections 33. Possibly, the through-connections 33 are arranged in groups of, for example, two through-connections 33 to achieve a reduced electric resistance between the main sides 311, 322. Seen in top view, the base body 30 may be of rectangular shape, for example, but other shapes are possible as well. The through-connections 33 and the conductor tracks 31 may be produced, for example, by using a sputtering process optionally followed by subsequent galvanization. For structuring of the conductor tracks lithographic approaches, etching processes and/or laser ablation processes can be used as well. Laser-aided deposition processes are also feasible.

According to FIG. 6, virtually the whole first main side 311 is coated with a material for the conductor tracks 31. The areas for the different conductor tracks 31 are separated from each other by means of separation lines 335 in which the first main side 331 is freed of the material for the conductor tracks 31. A width of the separation lines 335 is, for example, at most 2 mm or at most 0.5 mm or at most 0.2 mm and/or at least 50 μm or at least 10 μm. The separation lines 335 can be produced, for example, by laser ablation after fully coating the first main side 311, optionally including the through-connections 33.

A thickness of the material for the conductor tracks is, for example, at least 0.2 μm or at least 1.0 μm or at least 1.5 μm. Additionally or alternatively, said thickness is at most 20 μm or at most 5 μm or at most 3 μm.

In FIGS. 5 and 6, only the first main side 331 is shown. For the opposite, second main side 332 the same can apply as for the first main side 331 concerning the conductor tracks and the optional through-connections 33, and vice versa.

Otherwise, the same as to FIGS. 1 to 4 may also apply to FIGS. 5 and 6, and vice versa.

In FIG. 7, schematically an X-ray energy spectrum is shown wherein an intensity I is drawn vs. a photon energy E. There is a relevant energy detection range R in which, for example, there are the characteristic lines of metals like Fe, Cr and Ni. For example, the relevant energy detection range R may be from at least 0.1 keV to at most 0.2 MeV. Below the relevant energy detection range R, there is a low-energy range L. In the low-energy range L there are, for example, the characteristic lines of light elements like Si, Al, O, N or B. Possibly, for material analysis, this low-energy range L may not be of interest and may be cut off. Hence, characteristic lines in the low-energy range L may possibly not disturb the measuring by the X-ray detector 2.

Analogously, there is a high-energy range H above the relevant energy detection range R. For example, in the high-energy range H the X-ray detector 2 has no longer a significant detection efficiency and/or this energy range is of no particular interest in the respective application of the X-ray detection device 1.

Hence, by having the sensitive section 35 of the circuit board 3 it can be ensured that disturbing radiation within the relevant energy detection range R and arriving at the X-ray detector 2 from the circuit board 3 can greatly be reduced or avoided.

Otherwise, the same as to FIGS. 1 to 6 may also apply to FIG. 7, and vice versa.

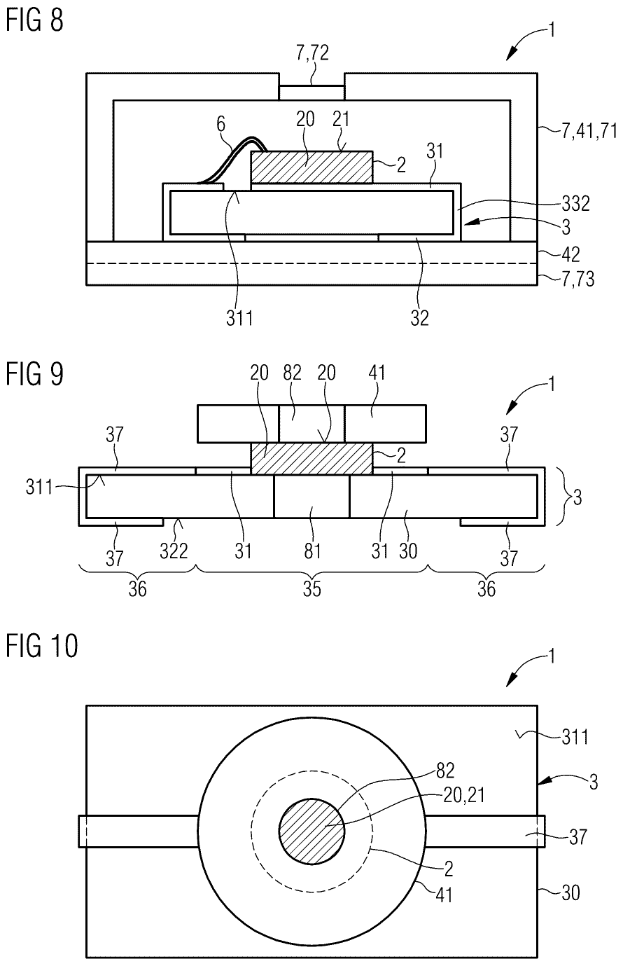

In the embodiment of FIG. 8, the X-ray detection device further comprises a housing 7. The housing 7 includes a housing cap 71, an X-ray window 72 and a housing socket 73. Hence, the X-ray detector 2 can be encapsulated in the housing 3. For example, the cap 71 is a first X-ray shielding element 41 that prevents exterior X-rays not coming through the X-ray window 72 from entering the X-ray detector 2. Further, the socked 73 can also include or can be a second X-ray shielding element 42. Such a housing 7, especially the housing cap 71, can also be present in all other embodiments.

However, X-rays may run through the window 72 and may not hit the X-ray detector 2 but the circuit board 3, for example. As the circuit board 3 is free of materials undergoing X-ray fluorescence in the relevant energy detection range R, disturbing radiation from the circuit board 3 is avoided.

As in all other embodiments, instead of electric through-connections the circuit board 3 can have the coating 332 at side faces electrically connecting the two main sides 311, 322. Hence, the conductor tracks 31, 32 and the coating 332 can be a manufactured as a single coating, for example. Optionally, the circuit board 3 may be attached at the socket 73 or optionally at a cooling unit, not shown in FIG. 8, by means of the second conductor tracks 32. An electric wiring of the socket 73 is not shown in FIG. 8.

Otherwise, the same as to FIGS. 1 to 7 may also apply to FIG. 8, and vice versa.

In FIGS. 9 and 10, another example of the X-ray detection device 1 is shown. The optional housing 7 is not illustrated for simplicity of the drawing.

The X-ray detection device 1 further includes a collimator having an aperture 82 as the first shielding element 41. By means of the collimator 41 it can be ensured that X-rays of the relevant energy detection range R can hit the active volume 20 only or virtually only through the aperture 82. The collimator 41 may directly be applied onto the X-ray detector 2.

Optionally, the collimator 41 extends beyond the X-ray detector 2. Hence, the collimator 41 may cover part of the circuit board 3, at least. Thus, the first conductor tracks 31 may further be protected from X-rays by means of the collimator 41. It is possible that the collimator 41 is congruent or approximately congruent with the sensitive section 35. The aperture 82 can be congruent with the active volume 20 or may be smaller than the active volume 20, seen in top view of the radiation entrance face 21.

As a further option, outside the sensitive section 35 there can be the further conductor tracks 37 so that there is the insensitive section 36.

Optionally, below the active volume 20 there can be a hole 81 in the circuit board 3. Hence, it is possible that below part of the X-ray detector 2 there is no material of the circuit board 3.

Otherwise, the same as to FIGS. 1 to 8 may also apply to FIGS. 9 and 10, and vice versa.

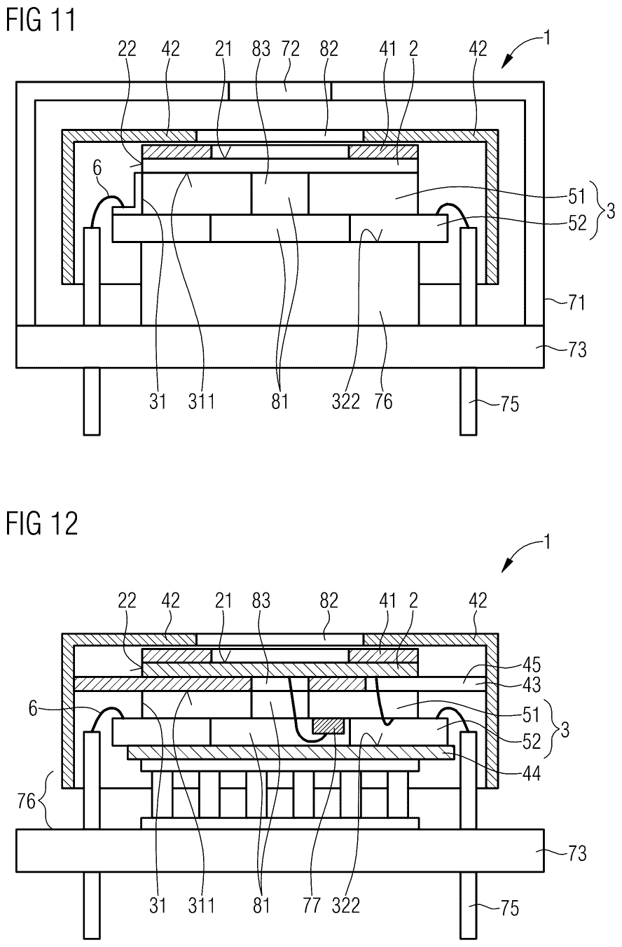

In FIG. 11, the X-ray detection device 1 further comprises a cooling unit 76, like a thermo-electric cooler, TEC. The circuit board 3 may directly be applied onto the cooling unit 76. Optionally, the housing includes contact pins 75 running through the socket 73. The circuit board 3 may electrically be connected with the pins 75 by bond wires 6, for example. The overall housing 7 may be a transistor outline, TO, housing.

In addition or alternatively to the collimator 41, there can be a second X-ray shielding element 42. For example, the shielding element 42 is formed like a cap. Hence, disturbing X-rays to the side faces 22 of the X-ray detector 2 can be shielded, for example.

As in all other embodiments, the circuit board 3 may have a three-dimensional, 3D, structure. Thus, the circuit board 3 comprises two circuit board layers 51, 52. The layer 51 next to the X-ray detector 2 may be congruent or approximately congruent with the X-ray detector 2. The layer 52 next to the cooling unit 76 may thus be larger. The layers 51, 52 can directly be stacked on one above, for example, in a rotational symmetric manner, seen in top view, not shown. Thus, the circuit board 3 may be composed of multiple, differently shaped sub-circuit-boards, some of which possibly not having a conduction track.

Optionally, the layers 51, 52 have holes 81 which can be of different sizes, for example. Thus, the overall circuit board 3 and the overall hole 81 may have the shape of a step pyramid or a step cone, for example. It is possible that the layers 51, 52 have different thicknesses. Otherwise, the layers 51, 52 may be of the same design concerning thickness and possibly also material composition. However, optionally, only the topmost layer 51 may be part of the sensitive section 35 while the lowermost layer 52 can include materials having an atomic number larger than 14.

As a further option, the conductor track 31 may run along the side face of the topmost layer 51. Thus, possibly said conductor track 31 can be connected with the bond wire 6, for example, on a side of the conductor track 31 facing away from the second layer 52. As in all other embodiments, thus, the conductor tracks 31, 32, 37 may be configured to enable wire bond connections. For example, a surface roughness Ra of the conductor tracks 31, 32 at a side facing away from the base body 30, is at most 0.8 μm or is at most 0.3 μm or is at most 50 nm.

Especially the lowermost layer 52 may comprise materials having an atomic number greater than 14. Because the lowermost layer 52 is protected from X-rays by means of the shielding elements 41, 42 and possibly by the socket 73, no significant amount of X-rays in the relevant spectral range may reach said materials so that X-ray fluorescence from these materials is inhibited or largely inhibited. The same applies for all other embodiments.

In FIG. 12, the cap 71 is not shown. Optionally, the cooling unit 76 may comprise a plurality of columns with TEC elements, like Peltier elements. To reduce disturbing X-ray fluorescence from the cooling unit 76 arriving at the X-ray detector 2, optionally there is a fourth X-ray shielding element 44 directly between the cooling unit 76 and the circuit board 3, for example. As a further option, there can be a third X-ray shielding element 43 directly between the X-ray detector 2 and the circuit board 3, for example. As the circuit board 3 does not produce disturbing X-ray fluorescence, the third X-ray shielding element 43 may have relatively large cutouts 45 to enable an efficient electric wiring between the X-ray detector 2, the circuit board 3 and the optional pins 75. The cap-shaped second shielding element 42 may replace the collimator 41 or may integrally be formed with the collimator. These aspects can individually or in any combination apply to all other embodiments as well.

As a further option, the circuit board 3 may carry one or a plurality of electric device 77, like IC chips. The electric device 77 may be shielded from the X-ray detector 2 by the base body of the circuit board 3 and/or by the optional third X-ray shielding element 43. For example, the at least one electric device 77 is mounted on a side of the first layer 51 facing away from the X-ray detector 2 and/or on the second main side 322 and/or on a side of the second layer 52 facing the X-ray detector 2.

As shown in FIG. 12, the first main side 311 of the circuit board 3 can completely be free of conductor tracks when using bond wires and conductor tracks on the second main side 322, that is, bond wires 6 may run from the radiation entrance face 21 and/or from the bottom side of the X-ray detector 2 directly to the second main side 322 and/or to the at least one electric device 77 and/or to sides of the layers 51, 52 facing away from the X-ray detector 2. Correspondingly, there can be cutouts and/or recesses in the circuit board 3, like the holes 81, allowing the bond wires 6 to pass through the circuit board 3, similar to the hole 81 and the cutout 45 through the third shielding element 43. If required, holes and/or cutouts may also be present in the first, second and/or fourth shielding elements 41, 42, 44 for electric wiring or assembly of the X-ray detection device 1. The same applies to all other embodiments of the X-ray detection device 1.

Concerning the configuration of the X-ray shielding elements 41, 42, 43, 44, reference is made to U.S. patent application Ser. No. 18/538,948, the disclosure content of which is hereby included by reference, compare especially FIGS. 12 and 17 of said US patent application and the associated description as well as, for example, claims 2, 3, 5, 6, 7, 19 and 20 therein.

Otherwise, the same as to FIGS. 1 to 10 may also apply to FIGS. 11 and 12, and vice versa.

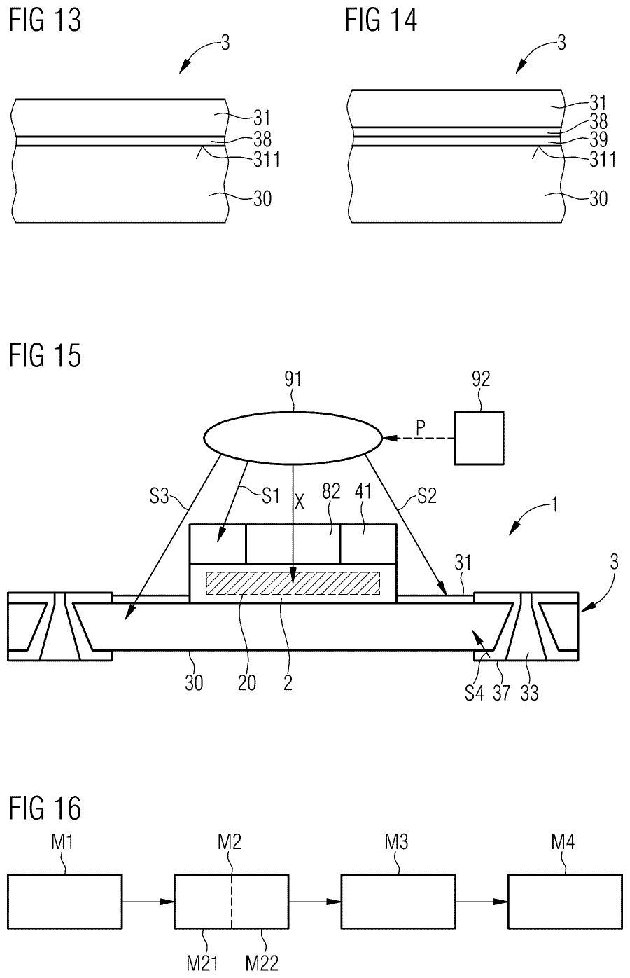

In FIG. 13 it is illustrated that the conductor track 31 can include an adhesion layer 38 between the base body 30 and a bulk material of the conductor track 31. Although possibly located in the sensitive section 35, the adhesion layer 38 may include materials having an atomic number larger than 14. This is enabled because the adhesion layer 38 is very thin, compared with the conductor track 31, so that the material of the adhesion layer 38 does not emit very much possibly disturbing X-rays upon being hit by stray X-rays. For example, a thickness of the adhesion layer 38 is at most 100 nm or at most 60 nm or at most 30 nm, compared with a typical thickness of the conductor track 31 of around 2 μm, for example. For example, the adhesion layer 38 is made of Ti, Cr or CrNi.

Such an adhesion layer 38 can also be present in all other embodiments of the conductor tracks 31, 332, 37.

According to FIG. 14, the base body 30 can be of a conductive or semiconductive material, for example, of aluminum or silicon. To enable the electric wiring, the base body 30 can partially or completely be coated with an insulation layer 39 made of, for example, silicon oxide, aluminum oxide, silicon nitride, aluminum nitride, boron nitride and/or boron carbide. A thickness of the insulation layer 39 is, for example, at least 10 nm or at least 30 nm and/or at most 2 μm or at most 1 μm or at most 0.3 μm.

Optionally, the adhesion layer 38 can also be present, either on one or on both sides of the insulation layer 39.

Otherwise, the same as to FIGS. 1 to 12 may also apply to FIGS. 13 and 14, and vice versa.

In FIG. 15, an X-ray system comprising the X-ray detection device 1 and a sample 91 as well as an X-ray source 92 is illustrated. The X-ray source 92 emits pump radiation P that excites the sample 91 to fluoresce in the X-ray spectral detection range. An X-ray X to be detected is emitted by the sample 91 and is absorbed in the active volume 20 to contribute to an electrical signal produced by the X-ray detector 2.

However, the sample 91 and/or the source 92 also emit X-rays in other directions. These other X-rays are referred to as stray lines S1 . . . S4. For example, the collimator 41 absorbs a stray X-ray S1. The stray X-rays S2 and S3 are absorbed by the conductor tracks 31 and the base body 20, respectively, but as the circuit board 3 is of materials having an atomic number of at most 14 in the sensitive section, the conductor tracks 31 and the base body 20 do not emit X-ray fluorescence in the relevant energy detection range R. Moreover, the possibly disturbing stray X-ray S4 within the relevant energy detection range R may be produced as X-ray fluorescence in the further conductor track 37, however, this stray X-ray S4 is absorbed in the base body 30, that is, the base body 30 needs to be sufficiently thick to guarantee sufficient absorption of the stray X-rays generated in the further conductor track 37.

Hence, a signal-to-noise ratio and/or a detection limit can be improved because of the circuit board 3 described herein.

Otherwise, the same as to FIGS. 1 to 14 may also apply to FIG. 15, and vice versa.

In FIG. 16, a manufacturing method for the X-ray detection device 1 is schematically illustrated. In a method step M1, the base body 30 of the circuit board 3 is provided. Then, in method step M2 the conductor tracks 31, 32, 37 are applied on the base body 30, either according to FIG. 5 or according to FIG. 6, Then, the X-ray detector 2 is applied on the circuit board 3. Finally, as an option, the electric wiring is established and/or the cooling unit 76 is installed and/or the socket 73 is applied and/or the at least one shielding element 41, 42, 43, 44 is mounted and/or the X-ray detector 2 is encapsulated by applying, for example, a housing cap 71 over the X-ray detector 2, like in FIG. 8 or 11.

Thus, a stray-line free metallized ceramic as the circuit board 3 can be produced. Hence, a circuit board 3 virtually ‘invisible’ for the respective X-ray spectroscopic application can be achieved, the circuit board 3 in particular does not produced characteristic X-ray lines within the relevant energy detection range R, also referred to as stray line or foreign line.

Thus, the base body as a substrate may be of a foreign line-free material like Al₂O₃, sapphire, SiO₂, fused silica, quartz, AlN, BN, high-temperature co-fired ceramics or HTCC for short, or high-temperature capable plastics provided with conductor tracks made of, for example, pure aluminum as a metallization also free of foreign lines. Optionally, there are the electric through-connections connected with the conductor tracks either on the first main side or on the second main side or on both main sides.

The at least one metallization can be applied by means of CVD or PVD processes, like sputtering, vapor deposition, atomic layer deposition, pulsed laser deposition, possibly in combination with a galvanic process. The metallization may be structured using etching and/or a lithographic process, for example, with a hard resist or a liquid resist. Structuring of the metallization is also possible, for example, by means of a laser, like an ultra-short pulsed laser or a continuous-wave laser or a pulsed laser. The metallization may also be applied with a doctor blade or by means of screen printing, for example, using a metal-filled paste. Chemical and/or electro-galvanic methods can be used as well for applying the metallization. Ink-jet printing and laser-aided deposition processes can further be used. Optionally, the adhesive layer can be used to enhance adhesion and/or to simplify application of the metallization. Such an at least one metallization can also be applied at side faces of the substrate and/or in the electric through-connections. The further conductor tracks can analogously be made of a further metallization that may include Cu, Ni, Au, Pd, Pt, Ag, Cr, Sn, In, W, Ta, Si and/or Ti, for example, at distinct solder pads or conductor track parts. Multi-layer metallization is also possible.

Thus, the metallization can be of a pure metal, like pure aluminum, and may especially be produced by a thin-film technique, like sputtering, or by means of a thick-film technique, like screen printing, see above. The at least one metallization can be produced current-less galvanically, or chemo galvanically or electro galvanically.

The manufactured base body may be of plane-parallel fashion or may have a 3D geometry. The base body may be of pure Al₂O₃, sapphire, SiO₂, fused silica, quartz, AlN, BN, high-temperature co-fired ceramics or HTCC for short, or high-temperature capable plastics with a purity of, for example, at least 90% or 95% or 99% by mass so that the base body does not produce disturbing X-ray fluorescence in the relevant energy detection range when being directly or indirectly excited X-ray coming from a sample or a natural or artificial external X-ray source.

A surface of the base body can be used as-fired, in case of a ceramic, or can undergo material removal, for example, can be milled, sanded, ground, polished and/or lapped.

The base body itself can also be made of an electrically conductive or semiconductive material, and the at least one metallization is deposited on the additional insulating layer on the base body. Further, the base body can be of an electrically insulating material the surface of which is made conductive; for example, AlN or a plastic can be used and can locally be made conductive by means of laser radiation, also referred to as laser direct structuring, or the like, possibly galvanic processes can additionally be applied to achieve a thicker metallization.

The circuit board and/or the base body can be of multi-layer fashion wherein the layers can have the same or indeed different set-ups concerning, for example, at least one of a thickness, material composition, design of the through-connections or design of the conductor tracks.

A composite of base bodies or circuit boards comprising of several individual base bodies or circuit boards can also be used. Such a composite can comprise equally sized or differently sized base bodies or circuit boards stacked on top of each other, whereby the base bodies or circuit boards are electrically conductively connected to each other or not, and may be connected by means of, for example, gluing, soft soldering, hard soldering, welding or the like. The individual base bodies or circuit boards may have a metallization or some of the base bodies or circuit boards may not have a metallization.

The electrical through-connections are made by forming holes into the volume of the base body, the surfaces of the holes are provided with a metal coating, for example. Such through-connections connect at least two otherwise non-contacting metallizations in an electrically conductive manner, whereby the metallizations to be connected can be applied to opposing planar surfaces, for example, such as a planar front side of the base body carrying the X-ray detector and a planar rear side of the base body as the main sides being arranged parallel with one another. If the respective electrical through-connection is in the sensitive section, the coating it is made of the at least one material with the atomic number of at most 14, like pure aluminum, so that the electrical through-connections do not lead to disturbing X-rays. Otherwise, if the electrical through-connections are in the insensitive section, they could comprise other materials as well. Concerning the applying the coating of the electrical through-connections, the same applies as for the producing the metallization. That is, for example, the coating for the electrical through-connections can be of single-layer fashion or of multi-layer fashion and optionally there can be present the adhesion layer and/or the insulation layer as well.

Hence, the at least one base body can additionally be provided with further metallizations and/or further electrical through-connections which comprise one or more metals like Cu, Ni, Au, Pd, Pt, Ag, Ti, Cr, Sn, In, W, Ta or alloys therefrom, having an atomic number greater than 14. Such further metallizations, which may generate foreign characteristic lines upon direct and/or indirect irradiation with X-Ray are positioned on the base body in such a way that they cannot be excited upon direct and/or indirect irradiation of the X-ray detection device with X-rays from an exterior of the X-ray detection device, at least in the relevant spectral range. If present, moreover, such further metallizations can be shielded in such a way that the foreign characteristic lines generated cannot be detected by the active volume of the X-ray detector or contribute to detected X-rays to a negligible extent. That is, at least one shielding element can be placed between the further metallization and the X-ray detector.

For example, such at least one further metallization can have improved bondability, like wire bondability, solderability, electrically conductive or insulating adhesiveness, compared with the at least one metallization made of the at least one material with the atomic number of at most 14.

The components shown in the figures follow, unless indicated otherwise, exemplarily in the specified sequence directly one on top of the other. Components which are not in contact in the figures are exemplarily spaced apart from one another. If lines are drawn parallel to one another, the corresponding surfaces may be oriented in parallel with one another. Likewise, unless indicated otherwise, the positions of the drawn components relative to one another are correctly reproduced in the figures.

The invention described here is not restricted by the description on the basis of the exemplary embodiments. Rather, the invention encompasses any new feature and also any combination of features, which includes in particular any combination of features in the patent claims, even if this feature or this combination itself is not explicitly specified in the patent claims or exemplary embodiments.

What is claimed is:

1. An X-ray detection device comprising:
a circuit board supporting conductor tracks on a base body; and
an X-ray detector mounted on the based body and configured to detect X-rays within a relevant energy detection range of the X-ray detection device,
wherein a sensitive section of the circuit board is free of contamination materials prone to emit contaminating X-ray emission within the relevant energy detection range upon being excited with X-rays, and
wherein in the sensitive section the base body and the conductor tracks consist essentially of circuit board materials having an atomic number of at most 14.

2. The X-ray detection device according to claim 1, wherein in the sensitive section the base body comprises at least one of an aluminum oxide, a silicon oxide, a boron nitride or an aluminum nitride with a purity of at least 95 mass-%, and wherein the conductor tracks comprises aluminum with a purity of at least 98 mass-%.

3. The X-ray detection device according to claim 1, wherein the sensitive section includes all regions of the circuit board from which X-rays of a specific photon energy are able to directly reach an active volume of the X-ray detector.

4. The X-ray detection device according to claim 1, wherein the circuit board further comprises an electrical through-connection running from a first main side to a second main side of the circuit board, and wherein the electrical through-connection comprises the circuit board materials.

5. The X-ray detection device according to claim 4, wherein the electrical through-connection comprises a hole and an electrically conductive coating covering side faces and a rim of the hole, and wherein the rim of the hole is in direct contact with the conductor tracks.

6. The X-ray detection device according to claim 5, wherein the hole is predominantly or completely filled with the electrically conductive coating.

7. The X-ray detection device according to claim 1,
wherein the circuit board comprises an insensitive section different from the sensitive section,
wherein the insensitive section includes at least one of the contamination materials having the atomic number greater than 14 and being prone to emit the contaminating X-ray emission within the relevant energy detection range upon being excited with X-rays, and
wherein the X-ray detector is mounted within the sensitive section.

8. The X-ray detection device according to claim 7, wherein the insensitive section is shielded from an active volume of the X-ray detector with respect to the relevant energy detection range.

9. The X-ray detection device according to claim 7, wherein the insensitive section is shielded from the X-ray detector by the base body.

10. The X-ray detection device according to claim 7, wherein the insensitive section comprises a further conductor track made of the at least one of the contamination materials having the atomic number greater than 14.

11. The X-ray detection device according to claim 10, wherein the further conductor track is located on a side of the base body remote from the X-ray detector.

12. The X-ray detection device according to claim 1,
wherein the circuit board consists of the sensitive section so that there is no insensitive section including at least one of the contamination materials having the atomic number greater than 14 and being prone to emit contaminating X-ray emission within the relevant energy detection range upon being excited with X-rays.

13. The X-ray detection device according to claim 1, further comprising a shielding element, wherein an insensitive section is shielded from stray X-rays by the shielding element.

14. The X-ray detection device according to claim 1,
wherein the conductor tracks further comprise an adhesion layer located directly between the base body and at least part of the conductor tracks,
wherein the adhesion layer comprises at least one of Cr, Ni or Ti, and
wherein a thickness of the adhesion layer amounts to at most 10% of a thickness of the conductor tracks.

15. The X-ray detection device according to claim 1, wherein the circuit board comprises a plurality of circuit board layers having different lateral extents, seen in top view onto the X-ray detector.

16. The X-ray detection device according to claim 15, wherein at least one of the conductor tracks runs along side faces of the circuit board layers, and/or wherein the X-ray detector is electrically connected with a side of the circuit board facing away from the X-ray detector by a bond wire, the bond wire passing through at least one of a hole or a cutout in the circuit board.

17. The X-ray detection device according to claim 1,
wherein the circuit board further comprises an insulation layer,
wherein the base body is semiconductive or electrically conductive, and
wherein the insulation layer is located directly between the conductor tracks and the base body.

18. A manufacturing method for producing the X-ray detection device according to claim 1, the method comprising
providing the base body of the circuit board;
applying the conductor tracks on the base body;
applying the X-ray detector on the circuit board; and
encapsulating the X-ray detector by applying a housing cap over the X-ray detector.

19. An X-ray detection device comprising:
a circuit board supporting conductor tracks on a base body;
an X-ray detector mounted on the base body and configured to detect X-rays within a relevant energy detection range of the X-ray detection device; and
a shielding element,
wherein a sensitive section of the circuit board is free of contamination materials prone to emit contaminating X-ray emission within the relevant energy detection range upon being excited with X-rays,
wherein, in the sensitive section, the base body and the conductor tracks consist essentially of circuit board materials having an atomic number of at most 14,
wherein, in the sensitive section, the base body comprises an aluminum oxide or a silicon oxide with a purity of at least 95 mass-%,
wherein the conductor tracks comprise aluminum with a purity of at least 98 mass-%,
wherein the sensitive section is shielded from stray X-rays by the shielding element, and
wherein the sensitive section includes all regions of the circuit board from which X-rays of a specific photon energy are able to directly reach an active volume of the X-ray detector.
